(19) United States
(12) Patent Application Publication
(10) Pub. No.: US 2025/0338403 A1
(43) Pub. Date: Oct. 30, 2025

(54) Microphone

(71) Applicant: AAC ACOUSTIC TECHNOLOGIES (SHENZHEN) CO., LTD., Shenzhen (CN)

(72) Inventors: Yaqi Wang, Shenzhen (CN); Zhongzong Gan, Shenzhen (CN); Rui Cai, Shenzhen (CN); Rui Zhang, Shenzhen (CN)

(21) Appl. No.: 19/007,595

(22) Filed: Jan. 2, 2025

Related U.S. Application Data
(63) Continuation of application No. PCT/CN2024/090750, filed on Apr. 30, 2024.

(51) Int. Cl. H05K 1/18; H04R 1/02; H04R 3/00; H04R 19/04; H05K 1/02

(52) U.S. Cl. CPC H05K 1/181; H04R 1/02; H04R 3/00; H04R 19/04; H05K 1/0218

(57) ABSTRACT

The present disclosure discloses a microphone including a shell, a printed circuit board enclosing a cavity together with the shell, a first chip assembly located in the cavity, and a second chip assembly embedded and accommodated in the printed circuit board. The printed circuit board is a multilayer structure including a chip mounting layer, a first alignment layer, a plurality of shielding layers, a second alignment layer, and an SMT layer arranged in sequence, each of the plurality of shielding layers is connected with a grounding point of the printed circuit board and provided with an avoiding aperture running through it. Compared with the related art, the microphone disclosed by the present disclosure could avoid a heat generated by the operation of the first AISC chip and the second ASIC chip affecting the performance of other devices.

### FIELD OF THE PRESENT DISCLOSURE

The present disclosure relates to a field of acoustic-electric conversion technology, in particular to a new microphone.

### DESCRIPTION OF RELATED ART

A microphone is a ring energy device that converts sound into electronic signals, and it mainly includes a housing, a circuit board enclosed with the housing to form a cavity, and a MEMS chip fixed on the circuit board and an ASIC chip fixed in the circuit board.

When the MEMS chip and the AISC chip in the related technology work together, the AISC chip will generate a large amount of heat, which will be dissipated through a substrate of the circuit board or through the thermal movement of the air in the cavity, and both of these ways of dissipation of heat will affect the performance of the other devices, especially those that are susceptible to the effects of heat.

Thus, it is necessary to provide a novel microphone to solve the problem.

### SUMMARY OF THE DISCLOSURE

The present disclosure is to provide a microphone which could avoid a heat generated by the operation of the printed circuit board or the thermal movement of the air affecting the performance of other devices.

For achieving the object mentioned above, the disclosure provides a microphone, including a shell; a printed circuit board covered and fixed with the shell and enclosing a cavity together with the shell; a first chip assembly fixed with one side of the printed circuit board close to the shell and located in the cavity; and a second chip assembly embedded and accommodated in the printed circuit board. The first chip assembly and the second chip assembly are electrically connected with each other and the printed circuit board, the shell or the printed circuit board is provided with an inlet sound hole through it, the printed circuit board is a multilayer structure including a chip mounting layer, a first alignment layer, a plurality of shielding layers, a second alignment layer, and an SMT layer arranged in sequence from one side close to the first chip assembly to the other side away from the first chip assembly, the chip mounting layer, the first alignment layer, the second alignment layer, and the SMT layer are electrically coupled to each other, the second chip assembly electrically is connected with the first alignment, each of the plurality of shielding layers is connected with a grounding point of the printed circuit board and provided with an avoiding aperture running through it, all avoiding apertures of the plurality of shielding layers collectively form an avoiding cavity, the second chip assembly is accommodated in the avoiding cavity.

Further, each of the chip mounting layer, the plurality of shielding layers, the first alignment layer, the second alignment layer, and the SMT layer is a metal layer.

Further, the printed circuit board includes a first conductive pillar which electrically connected with the second chip assembly, the first alignment layer, and the chip mounting layer in sequence.

Further, the printed circuit board further includes a second conductive pillar which electrically connected with the chip mounting layer, the first alignment layer, the second alignment layer, and the SMT layer, the avoiding aperture is used for avoiding the second conductive pillar.

Further, the first chip assembly includes a first MEMS chip and a second MEMS chip spaced apart from the first MEMS chip, the first MEMS chip and the second MEMS chip are fixed with the printed circuit board.

Further, the second chip assembly includes a first ASIC chip and a second ASIC chip spaced apart from the first ASIC chip, the first ASIC chip is electrically connected with the first MEMS chip, the second ASIC chip is electrically connected with the second MEMS chip.

Further, the first ASIC chip is electrically connected to the first MEMS chip via a first bond wire, and the second ASIC chip is electrically connected to the second MEMS chip via a second bond wire.

Further, one of FR4, ceramic, polyimide, and polyimide film material is filled between two adjacent structures of the multiple structure of the printed circuit board.

### BRIEF DESCRIPTION OF THE DRAWINGS

Many aspects of the exemplary embodiment can be better understood with reference to the following drawings. The components in the drawing are not necessarily drawn to scale, the emphasis instead being placed upon clearly illustrating the principles of the present disclosure.

FIG. 1 is a schematic diagram of a perspective structure of a microphone to an embodiment of the present disclosure;

FIG. 2 is a schematic diagram of a perspective structure of a printed circuit board of the microphone to an embodiment of the present disclosure;

FIG. 3 is a schematic diaphragm of a perspective structure of a plurality of shielding layers of the microphone to an embodiment of the present disclosure.

### DETAILED DESCRIPTION OF THE EXEMPLARY EMBODIMENTS

The present disclosure will hereinafter be described in detail with reference to exemplary embodiments. To make the technical problems to be solved, and technical solutions and beneficial effects of the present disclosure more apparent, the present disclosure is described in further detail together with the figure and the embodiment. It should be understood the specific embodiment described hereby is only to explain the disclosure, not intended to limit the disclosure.

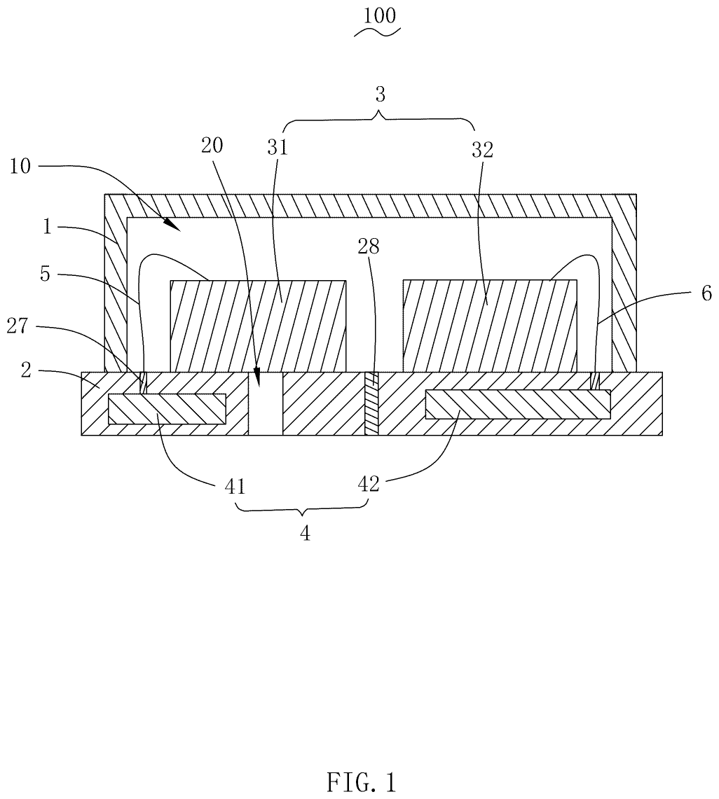

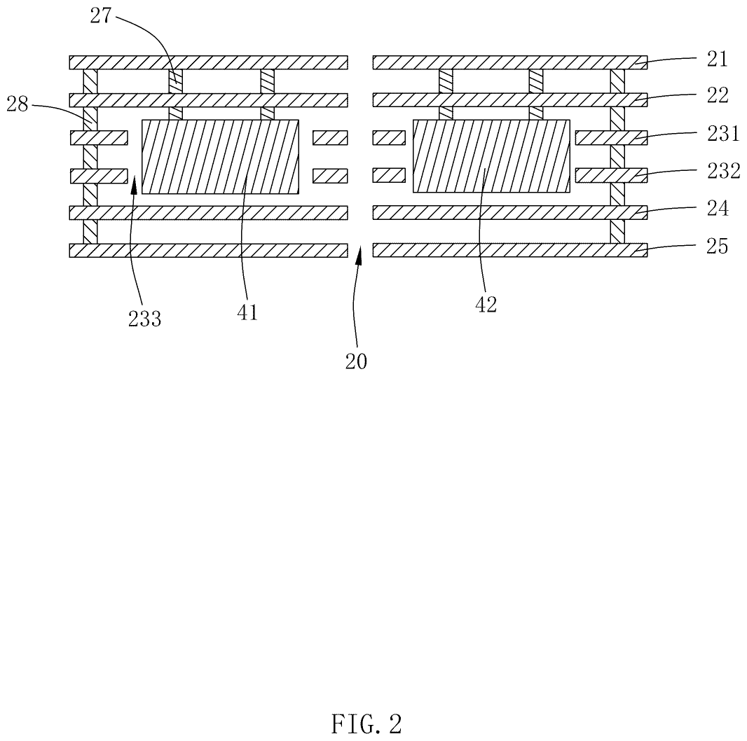

Referring to FIGS. 1-2, the present disclosure discloses a microphone 100, which includes a shell 1, a printed circuit board 2 covered and fixed with the shell 1 and enclosing a cavity 10 together with the shell 1, a first chip assembly 3 fixed with a side of the printed circuit board 2 close to the shell 1 and accommodated in the cavity 10, and a second chip assembly 4 embedded and fixed in the printed circuit board 2. The first chip assembly 3 and the second chip assembly 4 are electrically connected with each other and the printed circuit board 2.

The shell 1 or the printed circuit board 2 is provided with an inlet sound hole 20 through it. In this embodiment, the inlet sound hole 20 is provided on the printed circuit board 2.

The first chip assembly 3 includes a first MEMS chip 31 and a second MEMS chip 32 spaced apart from the first MEMS chip 31, the first MEMS chip 31 and the second MEMS chip 32 are fixed with the printed circuit board 2. The second chip assembly 4 includes a first ASIC chip 41 and a second ASIC chip 42 spaced apart from the first ASIC chip 41, the first ASIC chip 41 is electrically connected with the first MEMS chip 31, the second ASIC chip 42 is electrically connected with the second MEMS chip 32. In addition, the inlet sound hole 20 is covered by the first MEMS chip 31.

The first ASIC chip 41 is electrically connected to the first MEMS chip 31 via a first bond wire 5, and the second ASIC chip 42 is electrically connected to the second MEMS chip 32 via a second bond wire 6.

The printed circuit board 2 includes a first conductive pillar 27 which electrically connected with the second chip assembly 4, the first alignment layer 22, and the chip mounting layer 21 in sequence.

The printed circuit board 2 further includes a second conductive pillar 28 which electrically connected with the chip mounting layer 21, the first alignment layer 22, the second alignment layer 24, and the SMT layer 25.

The printed circuit board 2 is a multilayer structure including a chip mounting layer 21, a first alignment layer 22, a plurality of shielding layers, a second alignment layer 24, and an SMT layer 25 arranged in sequence from one side close to the first chip assembly 3 to the other side away from the first chip assembly 3, the chip mounting layer 21, the first alignment layer 22, the second alignment layer 24, and the SMT layer 25 are electrically coupled to each other, the second chip assembly 4 is electrically connected with the first alignment 22, each of the plurality of shielding layers is connected with a grounding point of the printed circuit board 2 and provided with an avoiding aperture 233 running through it, all of the avoiding apertures 233 of the plurality of shielding layers collectively form an avoiding cavity, the second chip assembly 4 is accommodated in the avoiding cavity.

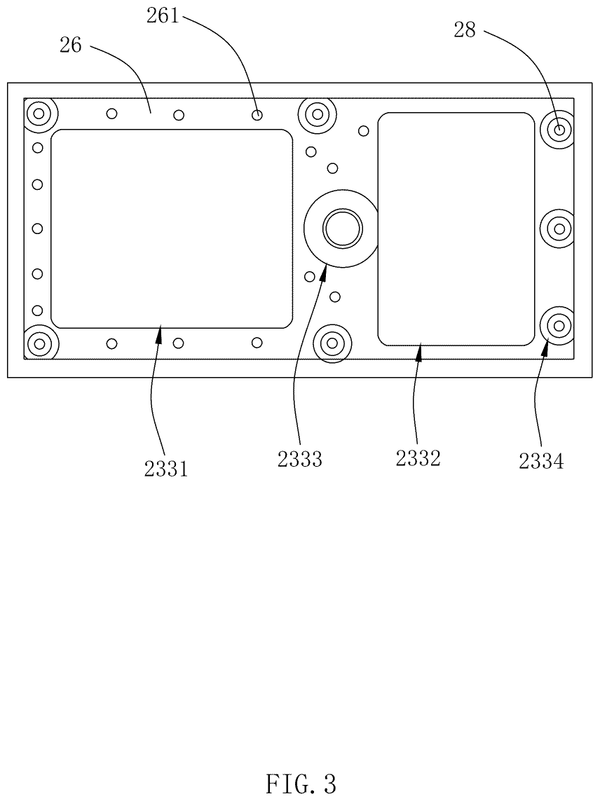

The printed circuit board includes at least six layer structures and at least two shielding layers, and the apertures holes 233 of the plurality of shielding layers are not only used for housing and avoiding the second chip assembly 4, but also for avoiding the second conductive pillar 28 or other structures of the printed circuit board 2 which need to be conduced. As shown in FIG. 3, each of the plurality of shielding layers has a plurality of avoiding holes forming an avoiding cavity for the first ASIC chip 2331, an avoiding cavity for the second ASIC chip 2332, an avoiding cavity for the first conductive pillar 2333, an avoiding cavity for the second conductive pillar 2334, an avoiding cavity for the inlet sound hole, and so on.

One of FR4, ceramic, polyimide, and polyimide film material is filled between two adjacent structures of the multiple structure of the printed circuit board 2.

In this embodiment, there is two shielding layers which include a first shielding layer 231 and a second shielding layer 232.

The grounding point (grounding layer) 26 is provided with a grounding layer conductive pillar 261 to realize a conductive function.

Each of the plurality of the shielding layers, the first alignment layer 22, the second alignment layer 24, and the SMT layer 25 is a metal layer, such as a copper layer, an aluminum layer, a nickel layer, a gold layer, a metal alloy layer, and so on.

Two ends of the first bond wire 5 are connected to a pad on the first conductive pillar 27 connected to the first ASIC chip 41 and a pad on the first MEMS chip 31, respectively. Two ends of the second bond wire 6 are connected to a pad on the first conductive pillar 27 connected to the second ASIC chip 42 and a pad on the second MEMS chip 32, respectively.

The pads on the printed circuit board 2 are located on the same or opposite sides of the printed circuit board 2 or in a central region of the printed circuit board 2.

According to practical needs, sensor chips such as pressure sensors, microphone sensors, and gas sensors could also be applied to the microphone 100 in this embodiment.

In this embodiment, the printed circuit board 2 is a multilayer structure including the chip mounting layer 21, the first alignment layer 22, the plurality of shielding layers, the second alignment layer 24, and the SMT layer 25 arranged in sequence from one side close to the first chip assembly 3 to the other side away from the first chip assembly 3, the chip mounting layer 21, the first alignment layer 22, the second alignment layer 24, and the SMT layer 25 are electrically coupled to each other, the second chip assembly 4 is electrically connected with the first alignment 22, each of the plurality of shielding layers is connected with the grounding point of the printed circuit board 2 and provided with an avoiding aperture 233 running through it, all avoiding apertures 233 of the plurality of shielding layers collectively form an avoiding cavity, the second chip assembly 4 is accommodated in the avoiding cavity. Therefore, the heat emitted during the operation of the first ASIC chip and the second ASIC chip inside the circuit board 2 can be exported to outside through the plurality of shielding layers and the grounding point 26 in turn, so as to reduce the interference of the heat emitted during the operation of the first ASIC chip and the second ASIC chip on the performance of other chips.

It is to be understood, however, that even though numerous characteristics and advantages of the present exemplary embodiment have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms where the appended claims are expressed.

What is claimed is:

1. A microphone, comprising:
a shell;
a printed circuit board covered and fixed with the shell and enclosing a cavity together with the shell;
a first chip assembly fixed with a side of the printed circuit board close to the shell and accommodated in the cavity; and
a second chip assembly embedded and accommodated in the printed circuit board; wherein
the first chip assembly and the second chip assembly are electrically connected with each other and the printed circuit board, the shell or the printed circuit board is provided with an inlet sound hole through it, the printed circuit board is a multilayer structure comprising a chip mounting layer, a first alignment layer, a plurality of shielding layers, a second alignment layer, and an SMT layer arranged in sequence from one side close to the first chip assembly to the other side away from the first chip assembly, the chip mounting layer, the first alignment layer, the second alignment layer, and the SMT layer are electrically coupled to each other, the second chip assembly is electrically connected with the first alignment, each of the plurality of shielding layers is connected with a grounding point of the printed circuit board and provided with an avoiding aperture running through it, all of the avoiding apertures of the plurality of shielding layers collectively form an avoiding cavity, the second chip assembly is accommodated in the avoiding cavity.

2. The microphone as described in claim 1, wherein each of the chip mounting layer, the plurality of shielding layers, the first alignment layer, the second alignment layer, and the SMT layer is a metal layer.

3. The microphone as described in claim 1, wherein the printed circuit board comprises a first conductive pillar which electrically connected with the second chip assembly, the first alignment layer, and the chip mounting layer in sequence.

4. The microphone as described in claim 3, wherein the printed circuit board further comprises a second conductive pillar which electrically connected with the chip mounting layer, the first alignment layer, the second alignment layer, and the SMT layer, the avoiding aperture is used for avoiding the second conductive pillar.

5. The microphone as described in claim 1, wherein the first chip assembly comprises a first MEMS chip and a second MEMS chip spaced apart from the first MEMS chip, the first MEMS chip and the second MEMS chip are fixed with the printed circuit board.

6. The microphone as described in claim 5, wherein the second chip assembly comprises a first ASIC chip and a second ASIC chip spaced apart from the first ASIC chip, the first ASIC chip is electrically connected with the first MEMS chip, the second ASIC chip is electrically connected with the second MEMS chip.

7. The microphone as described in claim 6, wherein the first ASIC chip is electrically connected to the first MEMS chip via a first bond wire, and the second ASIC chip is electrically connected to the second MEMS chip via a second bond wire.

8. The microphone as described in claim 1, wherein one of FR4, ceramic, polyimide, and polyimide film material is filled between two adjacent structures of the multiple structure of the printed circuit board.
